(19) United States
(12) Patent Application Publication
(10) Pub. No.: US 2012/0008249 A1
(43) Pub. Date: Jan. 12, 2012

(54) INSERT-MOLDED ION WIND FAN

(75) Inventors: Brian D. SAWYER, Palo Alto, CA (US); Christopher Hizer, Campbell, CA (US)

(73) Assignee: Ventiva, Inc., Santa Clara, CA (US)

(21) Appl. No.: 13/171,348

(22) Filed: Jun. 28, 2011

Related U.S. Application Data
(60) Provisional application No. 61/362,977, filed on Jul. 9, 2010.

(51) Int. Cl. H01T 23/00; H05K 13/00

(52) U.S. Cl. 361/230; 29/592.1

(57) ABSTRACT

An ion wind fan can be manufactured efficiently using insert molding. In one embodiment, the present invention includes an ion wind fan having an isolator with an emitter bus plate and an emitter attachment plate insert molded into isolator. A collector electrode is further insert molded into the isolator. The collector electrode is supported in part by two collector supports. One or more wire emitter electrodes are welded to the emitter bus plate at a first end of the emitter wires and to the emitter attachment plate at a second end of the emitter wires.

### CROSS-REFERENCE TO RELATED APPLICATIONS

This application claims the priority benefit of U.S. Provisional Patent Application 61/362,977 entitled “Ion Wind Fan Designs,” filed on Jul. 9, 2010, which is hereby fully incorporated by reference.

### FIELD OF THE INVENTION

The embodiments of the present invention are related to ion wind fans.

### BACKGROUND

It is well known that heat can be a problem in many electronics device environments, and that overheating can lead to failure of components such as integrated circuits (e.g. a central processing unit (CPU) of a computer) and other electronic components. Most electronics devices, from LED lighting to computers and entertainment devices, implements some form of thermal management to remove excess heat.

Heat sinks are a common passive tool used for thermal management. Heat sinks use conduction and convection to dissipate heat and thermally manage the heat-producing component. To increase the heat dissipation of a heat sink, a conventional rotary fan or blower fan has been used to move air across the surface of the heat sink, referred to generally as forced convection. Conventional fans have many disadvantages when used in consumer electronics products, such as noise, weight, size, and reliability caused by the failure of moving parts and bearings.

A solid-state fan using ionic wind to move air addresses the disadvantages of conventional fans. However, providing an ion wind fan that meets the requirements of consumer electronics devices presents numerous challenges not addressed by any currently existing ionic wind device.

### BRIEF DESCRIPTION OF THE DRAWINGS

FIG. 1 is a block diagram illustrating an ion wind fan implemented as part of thermal management of an electronic device;

FIG. 2A is a perspective view of an ion wind fan according to one embodiment of the present invention;

FIG. 2B is a widthwise cross-sectional view of the ion wind fan of FIG. 2A according to one embodiment of the present invention

FIG. 3A is an upstream elevation view of an ion wind fan according to one embodiment of the present invention;

FIG. 3B is a downstream elevation view of the ion wind fan of FIG. 3A according to one embodiment of the present invention;

FIG. 3C is a side elevation view of the ion wind fan of FIG. 3A according to one embodiment of the present invention;

FIG. 3D is a downstream perspective view of the ion wind fan of FIG. 3A according to one embodiment of the present invention;

FIG. 3E is an upstream perspective view of the ion wind fan of FIG. 3A according to one embodiment of the present invention;

FIG. 4A is a lengthwise cross-sectional view of an ion wind fan according to one embodiment of the present invention;

FIG. 4B is a lengthwise perspective cross-sectional view of the ion wind fan of FIG. 4A according to one embodiment of the present invention;

FIG. 5 a flow diagram illustrating a manufacturing process to produce an ion wind fan according to one embodiment of the present invention; and

FIG. 6 a block diagram illustrating ion wind fan manufacturing according to one embodiment of the present invention.

### DETAILED DESCRIPTION

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not necessarily be so limited; rather the principles thereof can be extended to other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

Ion wind or corona wind generally refers to the gas flow that is established between two electrodes, one sharp and the other blunt, when a high voltage is applied between the electrodes. The air is partially ionized in the region of high electric field near the sharp electrode. The ions that are attracted to the more distant blunt electrode collide with neutral (uncharged) molecules en route to the collector electrode and create a pumping action resulting in air movement. The high voltage sharp electrode is generally referred to as the emitter electrode or corona electrode, and the grounded blunt electrode is generally referred to as the counter electrode, getter electrode, or collector electrode.

The general concept of ion wind—also sometimes referred to as ionic wind and corona wind even though these concepts are not entirely synonymous—has been known for some time. For example, U.S. Pat. No. 4,210,847 to Shannon, et al., dated Jul. 1, 1980, titled “Electric Wind Generator” describes a corona wind device using a needle as the sharp corona electrode and a mesh screen as the blunt collector electrode. The concept of ion wind has been implemented in relatively large-scale air filtration devices, such as the Sharper Image Ionic Breeze.

### Example Ion Wind Fan Thermal Management Solution

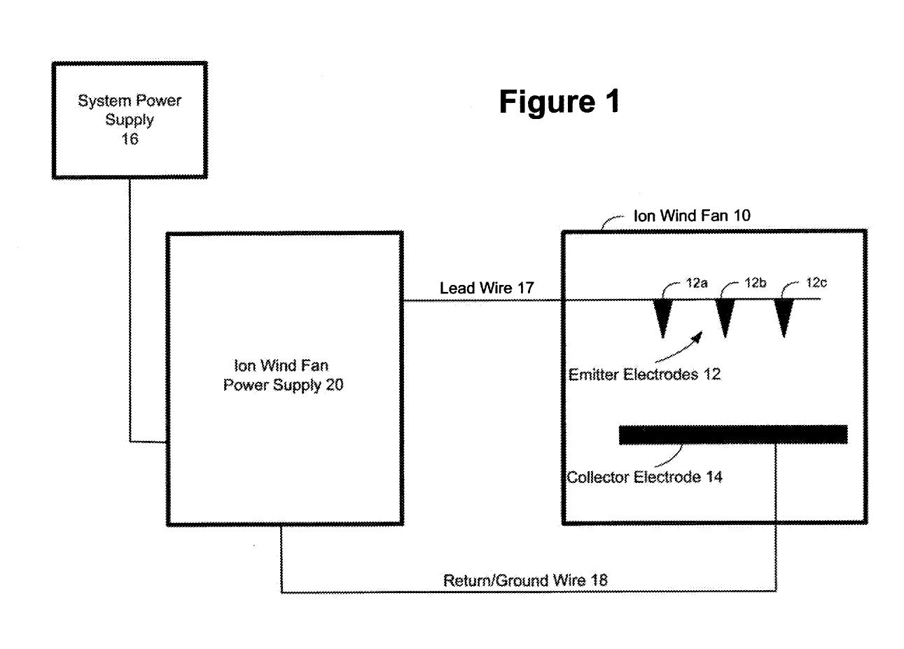

FIG. 1 illustrates an ion wind fan 10 used as part of a thermal management solution for an electronic device. As used in this application, the descriptive term “ion wind fan,” is used to refer to any electro-aerodynamic pump, electro-hydrodynamic (EHD) pump, EHD thruster, corona wind device, ionic wind device, or any other such device used to move air or other gas. The term “fan” refers to any device that move air or some other gas. The term ion wind fan is meant to distinguish the fan from conventional rotary and blower fans. However, any type of ionic gas movement can be used in an ion wind fan, including, but not limited to corona discharge, dielectric barrier discharge, or any other ion generating technique.

An electronic device may need thermal management for an integrated circuit—such as a chip or a processor—that produces heat, or some other heat source, such as a light emitting diode (LED). Some example systems that can use an ion wind fan for thermal management include computers, laptops, gaming devices, projectors, television sets, set-top boxes, servers, NAS devices, memory devices, LED lighting devices, LED display devices, smart-phones, music players and other mobile devices, and generally any device having a heat source requiring thermal management.

The electronic device can have a system power supply 16 or can receive power directly from the mains AC via a wall outlet, Edison socket, or other outlet type. For example, in the case of a laptop computer, the laptop will have a system power supply such as a battery that provides electric power to the electronic components of the laptop. In the case of a wall-plug device such as a gaming device, television set, or LED lighting solution (lamp or bulb), the system power supply 16 will receive the 110V mains AC (in the U.S.A, 220V in the EU) current from an electrical outlet or socket.

The system power supply 16 for such a plug or screw-in device will also convert the mains AC into the appropriate voltage and type of current needed by the device (e.g., 20-50V DC for an LED lamp). While the system power supply 16 is shown as separate from the IWFPS 20, in some embodiments, one power supply can provide the appropriate voltage to both an ion wind fan 10 and other components of the electronic device. For example, a single driver can be design to drive the LEDs of and LED lamp and an ion wind fan included in the LED lamp.

The electronic device also includes a heat source (not shown), and may also include a passive thermal management element, such as a heat sink (also not shown). To assist in heat transfer, an ion wind fan 10 is provided in the system to help move air across the surface of the heat source or the heat sink, or just to generally circulate air (or some other gas) inside the device. In prior art systems, conventional rotary fans with rotating fan blades have been used for this purpose.

As discussed above, the ion wind fan 10 operates by creating a high electric field around one or more emitter electrodes 12 resulting in the generation of ions, which are then attracted to a collector electrode 14. In FIG. 1, the emitter electrodes 12 are represented as triangles as an illustration that they are generally “sharp” electrodes. However, in a real-world ion wind fan 10, the emitter electrodes 12 can be implemented as wires, shims, blades, pins, and numerous other geometries. Furthermore, while the ion wind fan 10 in FIG. 1 has three emitter electrodes (12a, 12b, 12c), the various embodiments of the present invention described herein can be implemented in conjunction with ion wind fans having any number of emitter electrodes 12.

Similarly, the collector electrode 14 is shown simply as a plate in FIG. 1. However, a real-world collector electrode 14 can have various shapes and will generally include openings to allow the passage of air. The collector electrode 14 can also be implemented as multiple collector electrode members (e.g., rods, washers) held at substantially the same potential. Furthermore, in a real world ion wind fan 10, the emitter electrodes 12 and the collector electrode 14 would be disposed on a dielectric chassis—sometimes referred to as an isolator element—that has also been omitted from FIG. 1 for simplicity and ease of understanding.

To create the high electric field necessary for ion generation, the ion wind fan 10 is connected to an ion wind power supply 20. The ion wind power supply 20 is a high-voltage power supply that can apply a high voltage potential across the emitter electrodes 12 and the collector electrode 14. The ion wind fan power supply 20 (hereinafter sometimes referred to as “IWFPS”) is electrically coupled to and receives electrical power from the system power supply 16. Usually for electronic devices, the system power supply 16 provides low-voltage direct current (DC) power. For example, a laptop computer system power supply would likely output approximately 5-12V DC, while the power supply for an LED light fixture would likely output approximately 20-70V DC.

The high voltage DC generated by the IWFPS 20 is then electrically coupled to the emitter electrodes 12 of the ion wind fan 10 via a lead wire 17. The collector electrode 14 is connected back to the IWFPS 20 via return/ground wire 18, to ground the collector electrode 14 thereby creating a high voltage potential across the emitters 12 and the collector 14 electrodes. The return wire 18 can be connected to a system, local, or absolute high-voltage ground using conventional techniques.

While the system shown in and described with reference to FIG. 1 uses a positive DC voltage to generate ions, ion wind can be created using AC voltage, or by connecting the emitters 12 to the negative terminal of the IWFPS 20 resulting in a “negative” corona wind. Embodiments of the present invention are not limited to positive DC voltage ion wind. Furthermore, while the IWFPS 20 is shown to receive power from a system power supply 30, in other embodiment, the IWFPS 20 can receive power directly from an outlet.

The IWFPS 20 may include other components. Furthermore, in some embodiments, some of the components listed above may be omitted or replaced by similar or equivalent circuits. For example, the IWFPS 20 is described only as an example. Many different kinds and types of power supplies can be used as the IWFPS 20, including power supplies that do not have a transformers or other components shown in FIG. 1. The components described need not be physically separate, and may be combined on a single printed circuit board (PCB).

### Example Ion Wind Fan

As described partially above, ion wind is generated by the ion wind fan 10 by applying a high voltage potential across the emitter 12 and collector 14 electrodes. This creates a strong electric field around the emitter electrodes 12, strong enough to ionize the air in the vicinity of the emitter electrodes 12, in effect creating a plasma region. The ions are attracted to collector electrode 12, and as they move in air gap along the electric field lines, the ions bump into neutral air molecules, creating airflow. On a real world collector electrode 14, air passage openings (not shown) allow the airflow to pass through the collector 14 thus creating an ion wind fan.

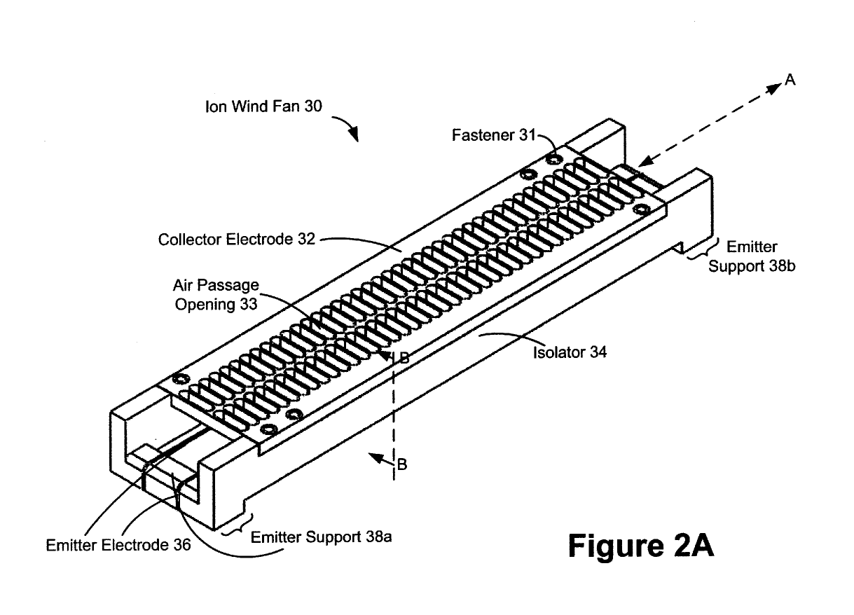

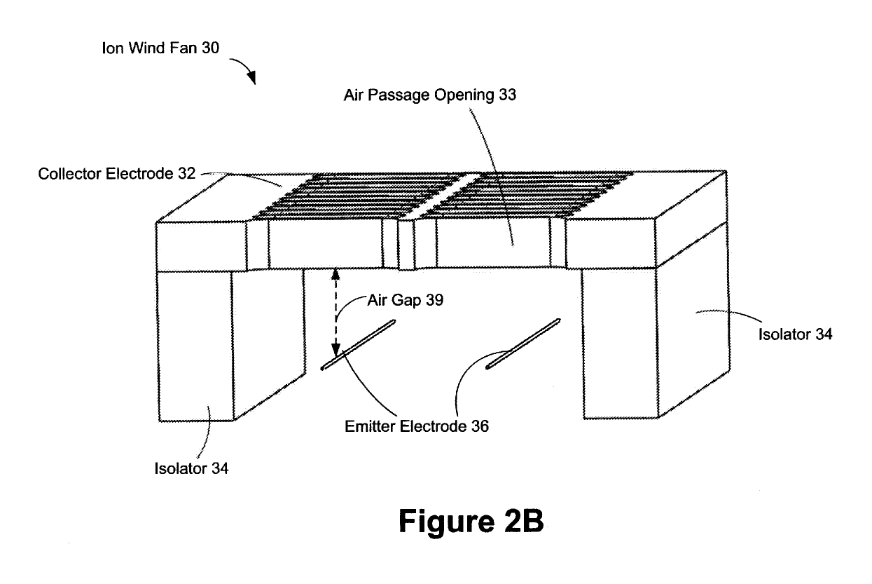

A previous ion wind fan design by the applicants of the present Application is now described with reference to FIGS. 2A and 2B for reference and comparison. FIG. 2A is a perspective view of an example ion wind fan 30. The ion wind fan 30 includes a collector electrode 32 having air passage openings 33 to allow airflow. This example ion wind fan 30 has two emitter electrodes 36 implemented as wires, thus implementing what is sometimes referred to as a “wire-to-plane” configuration.

The collector electrode 32 and the emitter electrodes 36 are both supported by an isolator 34. The isolator is made of a dielectric material, such as plastic, ceramic, and the like. The “isolator” component is thusly named as it functions to electrically isolate the emitter electrodes 36 from the collector electrode 32, and to physically support these electrodes. As such the isolator also can establish the spatial relationship between the electrodes, sometimes referred to under the rubric of electrode geometry. The isolator 34 can be made from one integral piece—as shown in FIG. 2A—or it can be made of multiple parts and pieces.

In the embodiment shown in FIG. 2A, the collector electrode is attached to the isolator using a fastener 31. The fastener 31 in FIG. 2 is a stake, but any other attachment method can be used, including but not limited to screws, hooks, glue, and so on. Similarly, the particular method of attachment of the emitter electrodes 36 is not essential to the embodiments of the present invention. The emitter electrodes 36 can be glued, staked, screwed, tied, held by friction, or attached in any other way to the isolator 34.

The ion wind fan 30—in the embodiment shown in FIG. 2A—is substantially rectangular in top view. The longitudinal axis of the ion wind fan 30 is denoted with the dotted arrow labeled “A.” The ion wind fan 30 has two ends opposite each other along the longitudinal axis. The emitter electrodes 36 are suspended between the two ends of the ion wind fan 30.

In one embodiment, the emitter electrodes 36 are supported at the ends of the ion wind fan 30 by an emitter support 38 portion of the isolator 34. The emitter support 38a at the left end of the ion wind fan 30 is most visible in FIG. 2A. The emitter support 38a is a portion of the isolator that physically supports the emitter electrodes 36. In one embodiment, the emitter electrodes 36 are suspended (in tension) between the two emitter supports 38 at the two ends of the ion wind fan 30.

In the embodiment shown in FIG. 2A, the isolator 34 has two elongated members oriented along the longitudinal direction that support the collector electrode 32, and the two elongated members (also referred to as sidewalls) are held joined by two cross-members that support the emitter electrodes 36. In one embodiment, these cross-members are oriented perpendicular to the elongated members (and thus the longitudinal axis). In FIG. 2A, these cross-members make up the emitter supports 38.

Thus, while in one embodiment the emitter support 38a is a substantially rectangular solid portion of the isolator 34 that connects the two elongated side portions of the isolator 34, in other embodiments the emitter supports 38 can have many other shapes and orientations. For example, a part of the center portion of the emitter support 38a between the emitter electrodes 36 could be cut away without substantially affecting the function of the emitter support 38a.

The emitter support 38a is shown as extending to the end of the ion wind fan 30. However, in other embodiments, the emitter support 38a can end before the end of the ion wind fan 30. The emitter support 38a is also shown as having a curved section at its outside edge to smooth out the 90 degree bend in the wire emitter electrodes 36. This is an optional feature not related to the embodiments of the present invention described herein.

Indeed, the actual attachment of the emitter electrodes 36 to either the emitter support 38 or some other portion of the isolator 34 is not material to the embodiments of the present invention, and therefore will not be discussed in much detail for simplicity and ease of understanding. The emitter electrodes 36 are shown as extending downward from the left end of the ion wind fan 30 and they are connected to the power supply via some wire or bus, as is the collector electrode 32. The emitter supports 38 need not have any particular shape of contact with the emitter electrodes 36. The emitter supports 38 are the portions of the isolator 34 that define the physical spatial relationship between the emitter electrodes 34 and other components of the ion wind fan 30.

FIG. 2B further illustrates the example ion wind fan 30 shown in FIG. 2A. FIG. 2B is a perspective cross sectional view of the ion wind fan 30 along the line B-B shown in FIG. 2A. The emitter electrodes 36 are suspended in air, and held a substantially constant air gap 39 distance away from the collector electrode 32.

Though wire sag and other emitter irregularities will create some variance, in one embodiment the air gap 39 between the emitter electrodes 36 and the bottom plane of the collector electrode 32 is substantially constant (within a 5% variation). In other embodiments, the air gap 39 can be more variable. The size of the air gap 39 is dependent on the spatial relationship between the electrodes established by the emitter supports 38 (which are not visible in FIG. 2B).

### Injection-Molded Ion Wind Fan

As explained above, the size of the ion wind fans being developed by the inventors is significantly smaller that the ionic wind applications of the prior art. This small size and small air gap between the emitter and collector electrodes makes certain designs advantageous that are not necessarily so for larger scale ionic air pumps. One such feature is an isolator having a tapered design, one embodiment of which is described below.

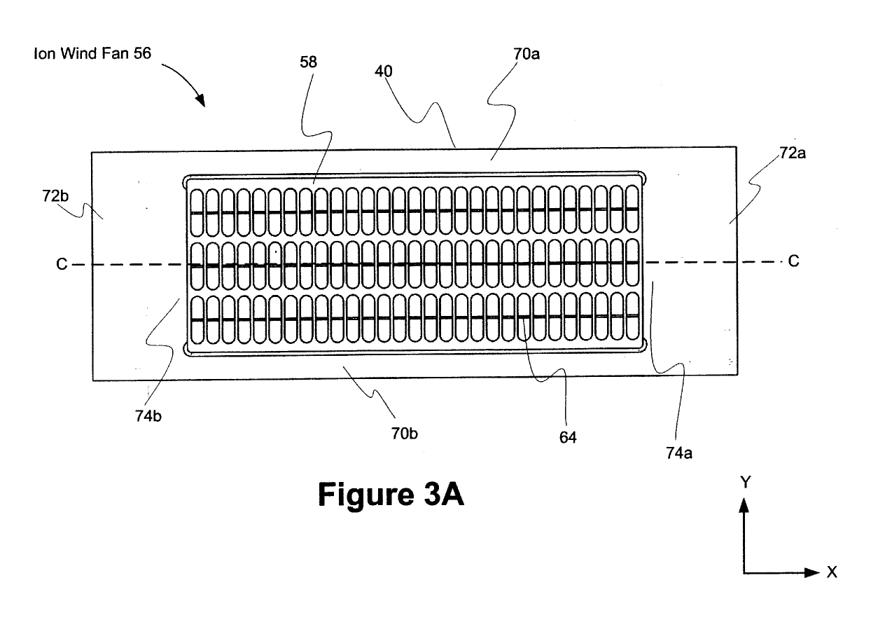

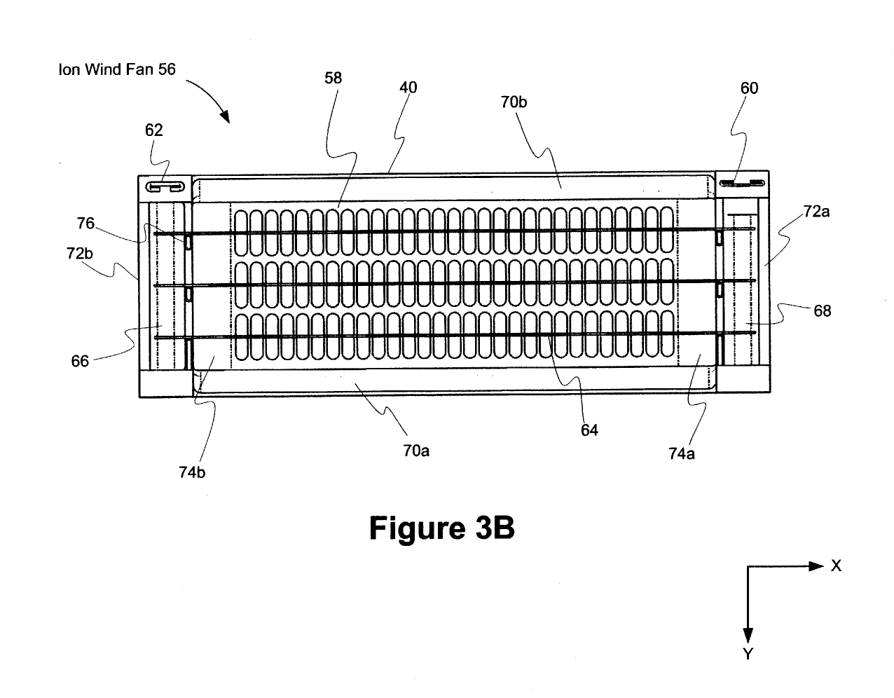

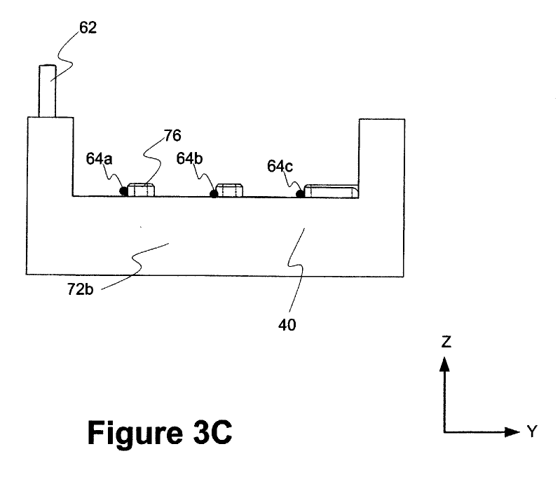

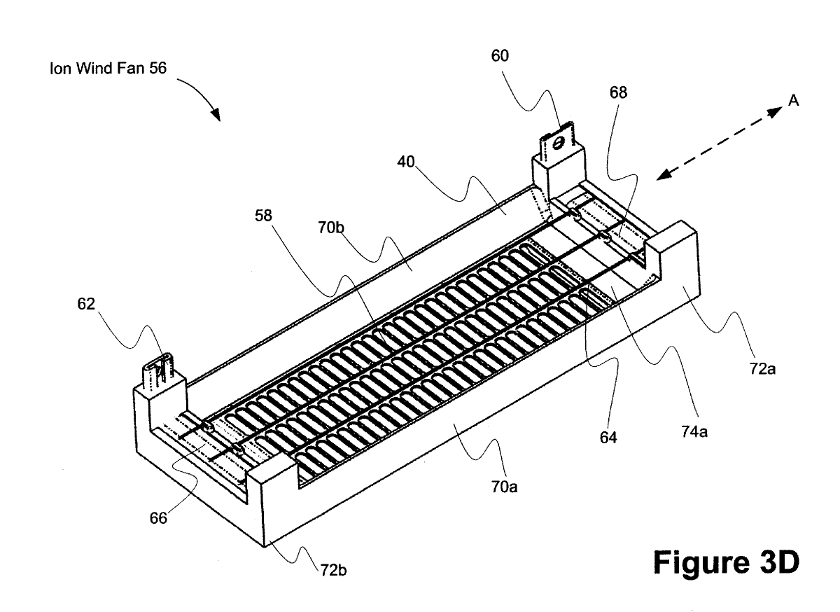

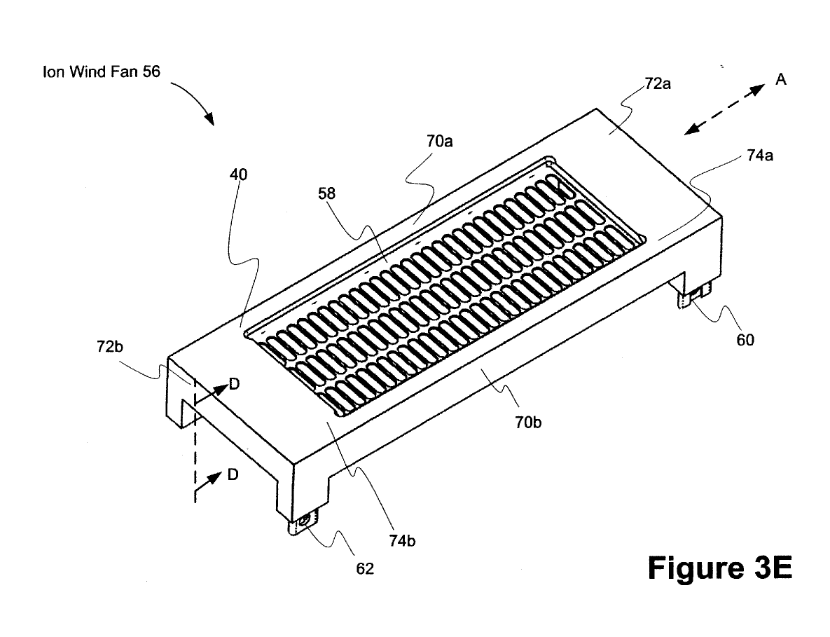

FIG. 3A is an “upstream” elevation view of an ion wind fan 56, so that the viewer is looking upstream and the wind from fan 56 would be blowing towards the viewer when in operation. From this view, the ion wind fan 56 of FIG. 3 is substantially similar to the ion wind fan 30 of FIG. 2. In this embodiment, the collector 58 is insert-molded into the isolator 40. The collector 38 is still substantially plane-like with air-passage openings, and the isolator 40 has a frame-like shape. The ion wind fan 56 is shown so that the X-axis corresponds with the longitudinal axis of the fan 56 and the Y-axis corresponds with the width direction of the fan 56. The unseen Z-axis corresponds with the depth of the fan 56.

The isolator 40 has two ends 72 longitudinally opposite each other, that also defined the end of the fan 56. The isolator ends 72 are also the widthwise sides of the isolator frame and include the emitter supports and attachments on their upstream sides. The emitter electrodes 64 are visible through the air-passage openings of the collector electrode 58. In the embodiment shown, from each isolator end portion 72 protrudes a collector support 74 into which the collector is insert-molded.

The sidewalls 70 or the isolator make up the long sides of the isolator's 40 frame-like rectangle, although in other embodiments they can be the short sides. In the case of wire emitter electrodes (such as in FIG. 3), the sidewalls are generally those portions of the isolator 40 that are oriented along the same general axis as the emitter wires (e.g., the X-axis in FIG. 3A).

FIG. 3B is a downstream elevation view of the ion wind fan 56, so that the airflow generated would blow away from the viewer along the Z-axis. The emitter electrodes 64, in this embodiment, are attached to plates 66, 68 on respective ends 72b, 72a or the ion wind fan 56. The bus plate 66 is electrically connected to the emitter prong 62 (for example by the bus plate 66 and the emitter prong 62 being formed from one piece of metal or other conductor), and is used to energize the emitter electrodes 64. The emitter prong 62 protrudes form the isolator 40, thus enabling the electrical coupling of the bus plate 66 to an IWFPS.

The attachment plate 68 is used to attach the emitter electrodes, in one embodiment, to the ion wind fan 56 at the opposite end 72a from the bus plate 66. The collector electrode 58 is electrically connected to the collector prong 60 used to ground, energize, or otherwise connect the collector electrode 58 to the power supply. The collector 58 and the collector prong 60 can be formed from one piece of metal or other conductor. The collector prong 60 also protrudes from the isolator, thereby enabling the electrical coupling of the collector electrode 58 to an IWFPS.

In one embodiment, in addition to being insert-molded into the sidewalls 70 of the isolator, the emitter electrode is also supported by the collector supports 74 that protrude from the fan end portions 72. The collector supports 74 can be part of the isolator 40, and are made of a dielectric. In one embodiment, in addition to providing support, the collector supports 74 prevent air recirculation by blocking airflow in areas not covered by the collector 58, as can also be seen in FIGS. 3A, 3B, 3D and 3E.

As shown in FIG. 3D, the collector support 74a protrudes from the end 72a portion of the isolator 40. Similarly, collector support 74v protrudes from the laterally opposite end 72b of the isolator. As shown, the collector supports 74 are rectangular protrusions that are solid. They extend from the collector electrode 58 to the fan/isolator ends 72 in the X-direction and from the left 70a to the right 70b sidewall in the Y-direction.

As such, the collector supports 74 ensure that all (or substantially all) airflow generated by the fan flows through the air passage openings of the collector electrode 58. This improves airflow by directing the air to higher velocity flows and by preventing recirculation around the edges of the collector electrode 58. This results in a significant improvement in efficiency over the ion wind fan design shown in FIG. 2, where recirculation around the longitudinal edges of the collector electrode 32 can occur.

In one embodiment, alignment posts 76 aid is the positioning of the emitter electrodes 64 during manufacturing. In one embodiment, the end portions 72, the sidewalls 70, the collector supports 74, and the alignment posts 76 are all parts of the isolator 40. The isolator 40 is made of a dielectric material, such as plastic, and can be formed in one single shot of injection molding.

Thus, all portions and pieces of the isolator are formed, in one embodiment, as one integral piece of dielectric material. In one embodiment, the dielectric material of which the isolator 40 is made is liquid-crystal polymer (LCP). LCPs are generally rigid, durable, and have desirable thermal properties that make them well-suited for providing isolation for an ion wind fan used for thermal management.

FIG. 3C is a side elevation view of the ion wind fan 56 sighting down the longitudinal X-axis from the side of the fan 56 having end portion 72b. The three emitter electrodes 64a,b,c are visible at their end, as well as the alignment posts 76. The airflow would substantially be in the negative Z-axis direction. In other embodiments the alignment posts 76 can be omitted, and the emitter wires 64 can be welded under controlled tension and position as described further below.

FIG. 3D is a perspective “downstream” view of the ion wind fan 56, so that the direction of the airflow is still towards the bottom of the page, as in FIG. 3C. The longitudinal axis (labeled “A”) of the ion wind fan 56 is shown, which is parallel to the X-axis of FIGS. 3A-C. In one embodiment, as can be seen in FIG. 3D, the sidewall 70b is tapered so that the sidewall is thicker in the Y-direction at the front of the fan 56 (closer to the collector 58 in the Z-direction) than it is at the bottom of the fan 56 (closer to the emitters 64 in the Z-direction). In the embodiment shown, the angle of the taper is about 30 degrees, but other taper degrees between 15-75 degrees can be used.

In one embodiment, the collector electrode 58 is stamped metal, and may or may not have some coating or plating on top of the base metal. In the embodiment shown, the collector electrode 58 is mostly flat with rows of ovalized/rounded rectangular air passage openings, each row being oriented parallel to the longitudinal axis “A,” which is also the orientation of the emitter electrodes (parallel to the X-axis).

The emitter electrodes 65, in one embodiment, are bused together and the bus is connected to or includes an emitter prong 62 that protrudes from the isolator 40. In the embodiment shown, the emitter prong 62 protrudes from the isolator in a direction (the Z-direction) perpendicular to the orientation of the collector electrode 58, the emitter electrodes and the longitudinal axis. However, in other embodiments, the emitter prong 62 can protrude in other directions. In one embodiment, power is supplied to the emitter electrodes 64 by connecting the emitter prong 62 to the high voltage ion wind fan power supply.

Similarly, the collector prong 60 connects the collector electrode 58 to the power supply, or to a ground. The collector prong 60 can protrude in other directions as well. In the embodiment shown, the collector prong 60 is located at the longitudinally opposite end of the ion wind fan 56 where the emitter prong 62 is located. In other embodiments, the collector prong 60 can be located on the same end of the ion wind fan 56 as the emitter prong 62.

In one embodiment, the emitter bus plate 66 and the emitter prong 62 are made of one metallic piece that is bent into an L-like shape and insert-molded into the isolator 40. In other embodiments other attachment methods can be used, such as glue and epoxy, and the emitter bus plate 66 can be made of a separate component from the emitter prong 62, which can be electrically coupled to the emitter bus plate 66.

The collector prong 60 shown in FIG. 3D can be a portion of the collector electrode 58 that is bent and insert-molded into the isolator 40 along with the collector electrode 58 with which it forms one integral piece of metal. In other embodiments, the collector electrode 58 and the collector prong 60 are separate components that are electrically coupled.

FIG. 3E is a perspective upstream view of the ion wind fan 56 showing all the elements previously numbered and described. Axis “A” once again represents the longitudinal axis of the fan 56. Various features on the upstream side of the ion wind fan 56, such as the emitter electrodes 64 are not visible in the view shown in FIG. 3E. Once again, the collector supports 74 are shown as solid portions of the isolator 40 with no air passage openings, so that the only air passage openings for the airflow generated by the ion wind fan 56 are located on the collector electrode 58.

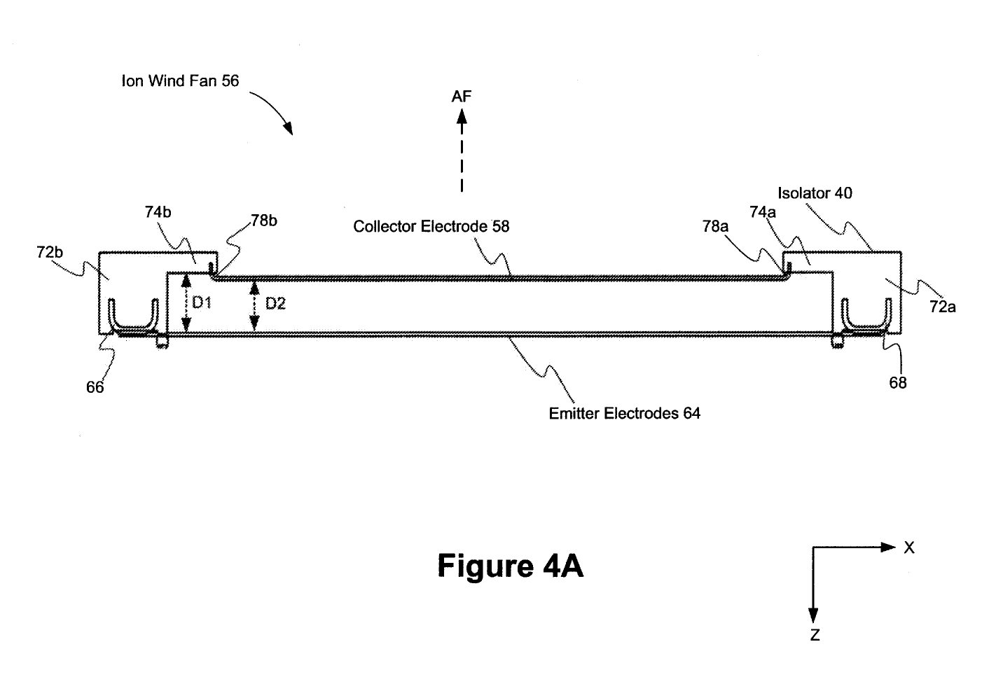

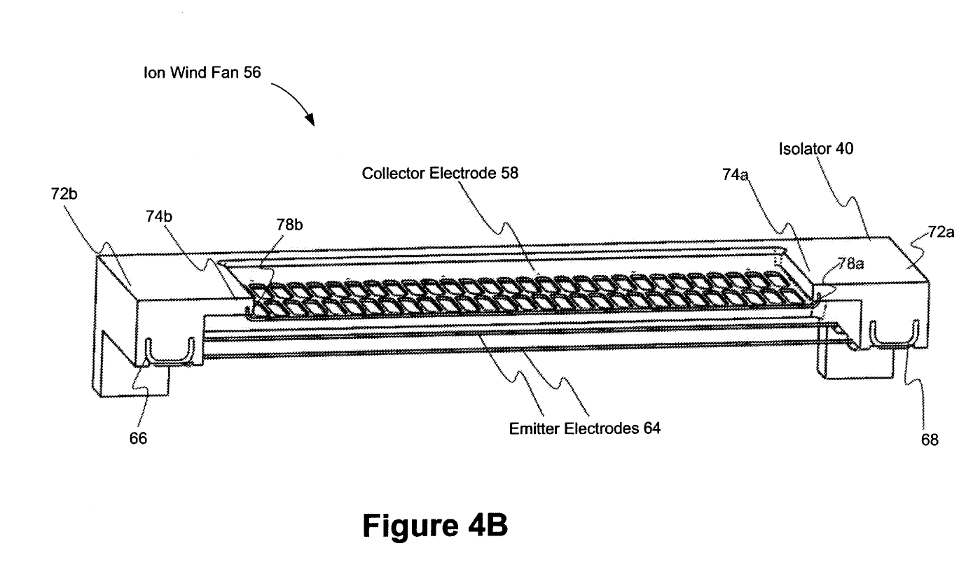

FIGS. 4A and 4B are cross-sectional views of the ion wind fan 56 taken at either the line C-C in FIG. 3A or the plane D-D in FIG. 3E. The air passage openings of the collector electrode are not shown in FIG. 4A, but are visible in FIG. 4B, which is a perspective cross-section. FIG. 4A shows the protrusion of the collector supports 74 from the fan/isolator ends 72.

In one embodiment, the collector electrode 58 is insert molded into the collector supports 74. In one embodiment, this is done so that the “neutralizing” or “active” upstream surface of the collector electrode 58 (i.e., the surface of the collector electrode 58 that faces the emitter electrodes 64) is closer to the emitter electrodes 64 than the upstream surface of the collector supports 74. Once again, the upstream surface of the collector supports 74 is the surface facing the emitter electrodes 64. In FIG. 4A, this relationship is illustrated by the double-sided arrows showing that D1>D2; D1 representing the distance between the upstream surface of the collector support 74b and the emitter electrodes 64, and D2 representing the distance between the upstream surface of the collector electrode 58 and the emitter electrodes 64.

In the embodiment shown in FIG. 4A, this geometry is accomplished by the collector electrode 58 having a curved portion 78 at both longitudinal ends, where the collector electrode curves away from the plane of the collector electrode that defines the active neutralizing surface, and curves in the downstream direction. As shown in FIG. 4A, after the 90 degree curved portion 78, the collector electrode has a surface oriented substantially perpendicular to the active plane of the collector electrode 58, and it is this surface that is used to insert mold the collector 58 into the isolator 40. In other embodiments, the curved portions 78 may implement curvatures that are less than 90 degrees or greater than 90 degrees.

In another embodiment, the desired geometry (D1>D2) can be accomplished by using a thicker collector electrode. However, a thicker collector electrode would add weight and cost to the ion wind fan, and would require more expensive stamping machinery. In one embodiment, the thickness of the collector electrode is about 5 mils (about 127 microns).

In one embodiment the air gap (D2) between the collector 58 and the emitters 64 is about 2mm and the operational voltage of the ion wind fan 56 does not exceed about 5 kV. In such an embodiment, the difference between D2 and D1 can be about 300 microns. Thus, in some embodiments, the difference between D2 and D1—that is the distance between the surface of the collector support 74 and the upstream surface of the collector electrode 58) is greater than the thickness of the collector electrode 58 itself. In one embodiment, the difference between D2 and D1 is between two to four times that of the thickness of the collector electrode 58.

Thus, in the embodiment described, D1 can be about 2.3 mm. So in such an embodiment D1 is about 15% larger than D2. Since the distances depend on geometry and operating parameters, in other embodiment D1 may be as little as 5% larger than D2 or as much as 25% larger than D2. For example in an embodiment having a maximum 5 mm air gap between the emitters 64 and the collector 58, operating at 10 kV D1 may be 5.5 mm.

Another aspect of one embodiment of the present invention that becomes visible in FIG. 4A is the shape of the emitter bus plate 66 and the emitter attachment plate 68. As seen in FIG. 4A, in one embodiment, the name “plate” does not accurately describe the shape of these components. However, since only the plate-like portions of these components protrude from the isolator—in the embodiment shown—they are referred to as plates.

In fact, in one embodiment, the emitter bus plate 66 is substantially U-shaped. The two “legs” of the U are used to better insert-mold the bus plate 66 into the isolator 40, as can be seen in FIG. 4A-B. The “top” part of the U-shape protrudes from the isolator 40 (at the fan ends 72) to present a flat or locally substantially flat surface for welding the emitter wires 64. In one embodiment, the bus plate is made of one integral piece of conductor (metal) as the emitter prong 62.

As described above, the emitter prong 62 protrudes from the isolator 40 at any desired location where the high voltage power supply can be coupled to the emitter prong 62. The exact location of the emitter prong is application specific, with the example shown in FIG. 3D being one embodiment. The emitter prong may protrude from the isolator at any location, and need not be located at the fan end 72b.

In one embodiment, the emitter attachment plate 68 is substantially similar to the emitter bus plate 66, with the exception that the emitter attachment plate 68 need not be coupled to the emitter prong 62. Since the emitter attachment plate 68 is coupled to the emitter wires 64, it will be at or about the same potential as the emitter wires 64.

Thus, in other embodiments, the emitter bus plate 66 and the emitter attachment plate 68 can be formed of one integral piece of conductor. The connecting portion can be contained entirely inside of the isolator 40. In such an embodiment, both the emitter bus plate 66 and the emitter attachment plate 68 would be coupled directly to the emitter prong 62, as all three would be made of one integral piece of conductor. In one embodiment, the U-shaped portions of the bus 66 and attachment 68 plates includes one or more openings to allow better plastic flow during the insert molding process.

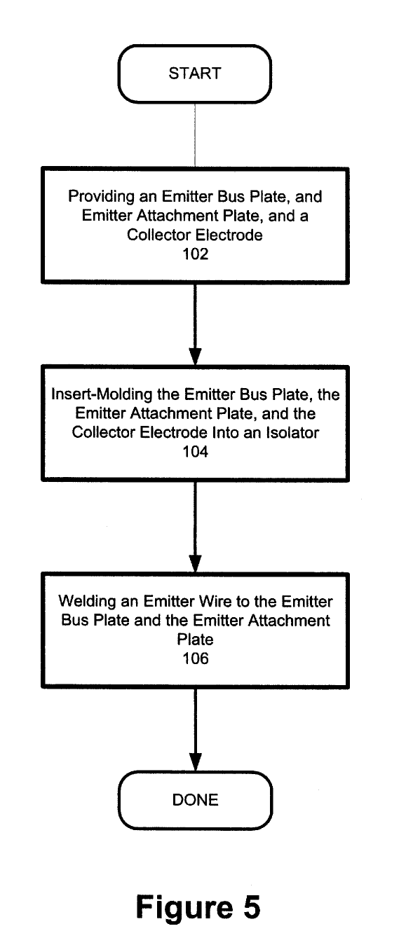

One embodiment of the insert molding process in now described with reference to FIG. 5. The process begins at block 102 with the provision of an emitter bus plate, attachment plate, and a collector electrode. All of these metal components can be made by stamping of stainless steel into the desired shapes.

As described above, in one embodiment the bus and attachment plates and the emitter prong are made of one piece of stamped metal. Similarly, the collector electrode and the collector prong are made of one piece of stamped metal. In other embodiment, the metal components can be formed by processes other than stamping, such as machining, molding, ect.

In block 104, the metal components are insert-molded into an isolator made of a dielectric. LCP can be injection molded to contain the metal components in the desired geometry. One advantage of making the bus and attachment plates from one piece of metal is the simplification of the insertion and positioning process during insert-molding in block 104. Then, in block 106, one or more emitter wires are welded to the bus and attachment plates, as described further below.

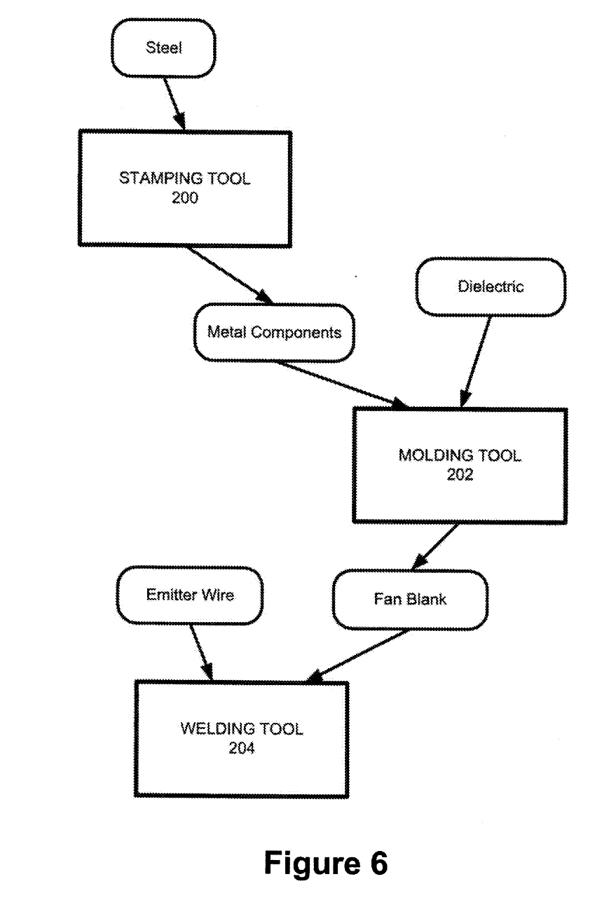

FIG. 6 is a block diagram illustrating one embodiment of a production process, such as the one shown in FIG. 5. In one embodiment, steel plates are provided to a stamping tool 200, that stamps out the metal components described above. These components and a dielectric, such as LCP, as provided to a molding tool 202 operable to insert-mold the metal components into the dielectric isolator in the desired geometry.

The output of the molding tool 202 is a “fan blank” which has essentially all the parts of the ion wind fan, except for the emitter wires. Thus, the fan blank and the wires are provided to a welding tool 204. In one embodiment, the welding tool holds the fan blank upside down (as in FIG. 3D) and first welds the emitter wires to the plate at one end of the ion wind fan. Any excess wire is cut off and discarded.

Then, the welding tool advances the fan blank or the wires in such a manner that tension is maintained on the wires. In one embodiment, a constant torque wheel can be used to maintain tension. Such torque wheels have been used to keep wire spools from unspooling. However, by adjusting the back-torque of the constant torque wheel, the emitter wire spool can be used to tension the emitter wires during welding. The exact amount of back-torque is applications specific and depends on the length of the fan and the thickness of the wires. In one embodiment the tensioning mechanism provides between 15-125 grams of torque.

While the wires are tensioned, they are welded to the plate at the opposite end of the ion wind fan. Again, any excess wire is cut and discarded. If the welding tool 204 is operable at high precision, no alignment posts are needed for the emitter positioning. However, in other embodiment, they can be used to allow lower tolerance weld positioning machinery. In one embodiment, the welding tool 204 uses resistance welding to perform the wire welds. In one embodiment the resistance welder uses between 50-150 amps for the welding operation.

One advantage of a the design shown and described with reference to FIGS. 3 and 4 is that the welding of the emitter wires can be done after the insert molding of the collector electrode is a simple cost effective manner. Since the exposed welding surface of the emitter bus and attachment plates (collectively the emitter attachment component) face upstream—instead of downstream as in the design shown in FIG. 2—the emitters welding can be easily done on a fan blank that includes a collector electrode. Thus, in one embodiment, the welding surface faces substantially the same way as the upstream surface of the collector electrode.

While the example ion wind fans described and pictured above are shown as having either two or three emitter electrodes, any number of emitter electrodes can be used, including one, to create one or more-channel ion wind fans. While most electronics cooling applications using a wire emitter will have between 1-10 emitter electrodes, the invention is not limited to any range of emitter electrodes used. For example, a pin-grid emitter configuration would likely use 10s or 100s of electrodes.

While the embodiments were generally described in the context of positive DC corona applications, the embodiments of the present invention are similarly applicable to negative DC corona, AC corona, or other non-corona ion wind applications without substantial modifications. Furthermore, while the chamfering or tapering of the isolator has described as occurring on the sidewall of the isolator, these inventive aspects of the present invention can be implemented on any portion of any isolation structure of an ion wind fan.

In the descriptions above, various functional modules are given descriptive names, such as “ion wind fan power supply.” The functionality of these modules can be implemented in software, firmware, hardware, or a combination of the above. None of the specific modules or terms—including “power supply” or “ion wind fan”—imply or describe a physical enclosure or separation of the module or component from other system components.

Furthermore, descriptive names such as “emitter electrode,” “collector electrode,” “isolator,” and “sidewall” are merely descriptive and can be implemented in a variety of ways. For example, the “collector electrode,” can be implemented as one piece of metallic structure, but it can also be made of multiple members spaced apart, and connected by wires or other electrical connections to the same voltage potential, such as ground.

Similarly, the isolator can be the substantially frame-like component shown in FIGS. 2-4, but it can have various shapes. The electrodes and the isolator are not limited to any particular material; however, the isolator will generally be made of a dielectric material, such as plastic, ceramic, and other known dielectrics.

The isolator 40 can be made of one piece of injection-molded dielectric, but it can be made up of several pieces attaches together. Furthermore, the various portions of the isolator, such as the collector support, emitter support, and internal sidewall are sometimes defined functionally. For example, since the emitter support and the collector support are adjoining portions of the isolator, it may not be important to spatially define exactly where the boundary between these two portions is.

1. An ion wind fan having a longitudinal axis, the ion wind fan comprising:
an isolator comprising a dielectric, the isolator having a first end and a second end longitudinally opposite the first end, wherein the first end comprises an emitter bus plate insert molded into the first end and the second end comprises an emitter attachment plate insert molded into the second end;
a collector electrode insert molded into the isolator, the collector electrode being supported at least in part by a first collector support protruding from the first end and a second collector support protruding from the second end; and
one or more wire emitter electrodes welded to the emitter bus plate at a first end of the emitter wires and to the emitter attachment plate at a second end of the emitter wires and held in tension across the first and second ends of the ion wind fan.

2. The ion wind fan of claim 1, wherein the emitter bus plate comprises a substantially U-shaped piece of metal.

3. The ion wind fan of claim 2, wherein only a plate or dome-like portion of the U-shaped piece of metal protrudes from the isolator.

4. The ion wind fan of claim 2, wherein the emitter attachment plate comprises a second substantially U-shaped piece of metal.

5. The ion wind fan of claim 4, wherein only a plate or dome-like portion of the second U-shaped piece of metal protrudes from the isolator.

6. The ion wind fan of claim 1, wherein the emitter bus plate and the emitter attachment plate comprise one integral piece of metal.

7. The ion wind fan of claim 1, further comprising an emitter prong protruding from the isolator, the emitter prong being electrically coupled to the emitter bus plate.

8. The ion wind fan of claim 7, wherein the emitter prong and the emitter bus plate comprise one integral piece of metal.

9. The ion wind fan of claim 1, wherein the collector electrode comprises a substantially flat plane of metal having an upstream surface facing the emitter electrodes and a downstream surface, the collector electrode having a plurality of air-passage openings.

10. The ion wind fan of claim 9, wherein the collector electrode comprises a first curved portion at a first longitudinal end that curves the first end portion away from the plane of the upstream surface of the collector electrode.

11. The ion wind fan of claim 10, wherein the collector electrode comprises a second curved portion at a second longitudinal end that curves the second end portion away from the plane of the upstream surface of the collector electrode, wherein the collector electrode in insert molded into the first collector support at the first end portion and the collector electrode is further insert molded into the second collector support at the second end portion.

12. The ion wind fan of claim 9, wherein the distance between the emitter electrodes and the upstream surface of the collector electrode is less than the distance between the emitter electrodes and the first collector support.

13. The ion wind fan of claim 12, wherein the difference between the distance between the emitter electrodes and the first collector support and the distance between the emitter electrodes and the upstream surface of the collector electrode is greater than the thickness of the collector electrode between the upstream and downstream surfaces of the collector electrode.

14. The ion wind fan of claim 9, wherein the first and second collector supports comprise solid surfaces that block airflow so that substantially all of the airflow generated by the ion wind fan is through the air-passage openings of the collector electrode.

15. The ion wind fan of claim 8, further comprising a collector prong protruding from the isolator, the collector prong being electrically coupled to the collector electrode.

16. The ion wind fan of claim 15, wherein the collector prong and the collector electrode comprise one integral piece of metal.

17. The ion wind fan of claim 16, wherein the ion wind fan is energized by electrically coupling the emitter prong to the high side of a high voltage power supply and electrically coupling the collector prong to the low side of the high voltage power supply.

18. A method of manufacturing an ion wind fan, the method comprising:
operating a metal stamping tool to generate an emitter attachment component and a collector electrode;
operating a molding tool to generate a fan blank by insert molding the emitter attachment component and the collector electrode into an injection molded isolator made of a dielectric; and
operating a welding tool to generate the ion wind fan by welding one or more emitter wires to portions of the emitter attachment component that protrude from the isolator.

19. The method of claim 18, wherein the welding tool comprises a tensioning mechanism to keep tension on the emitter wires such that the emitter wires are held in tension after welding.

20. The method of claim 18, wherein the dielectric comprises liquid crystal polymer (LCP).
